(19) United States
(12) Patent Application Publication
(10) Pub. No.: US 2025/0048603 A1
(43) Pub. Date: Feb. 6, 2025

(54) HEATSINK FOR ELECTRIC COMPONENT OF POWER EQUIPMENT, POWER EQUIPMENT INCLUDING SAME, AND METHOD

(71) Applicant: Honda Motor Co., Ltd., Tokyo (JP)

(72) Inventor: Toshiyuki HASEGAWA, Durham, NC (US)

(21) Appl. No.: 18/365,702

(22) Filed: Aug. 4, 2023

(51) Int. Cl. H05K 7/20; A01D 34/78

(52) U.S. Cl. CPC H05K 7/209; A01D 34/78; H05K 7/20418; A01D 2101/00

(57) ABSTRACT

A heatsink for cooling an electric component of a power equipment can include a plurality of convective surfaces spaced away from and overlapping each other, and a first rivet connecting the convective surfaces to each other. The power equipment can be a lawnmower, a snow blower, a pressure washer, a tiller, a hedge trimmer, a string trimmer, a power saw, a fluid pump, a portable cooler, an E-Bikes and a scooter.

### BACKGROUND

The disclosed subject matter relates to methods and apparatus that can transfer heat from an electric component to the ambient environment using natural convection. More particularly, the disclosed subject matter relates to a heatsink for an electric component of a power equipment.

Power equipment such as lawnmowers, snow blowers, pressure washers, tillers, hedge trimmers, string trimmers, power saws, portable coolers, E-Bikes and scooters can be operated by an electric motor, or a hybrid of an internal combustion engine and an electric motor. Power equipment can include a protective housing that encloses the electric component(s) and be configured to shield the electric component(s) from dust, debris and liquids. However, during operation of the power equipment, the electric component(s) can generate heat. This generated heat can also adversely affect the electric component(s) if the generated heat is not transferred to the ambient environment to allow for cooling of the electric component(s).

Power equipment can include a heat exchanger that can transfer heat from one or more electric components to the ambient environment. The heat exchanger can be configured as a fluid-to-fluid heat exchanger or as a heatsink. The heatsink can absorb heat from the component(s) via heat conduction and dissipate the absorbed heat to the ambient environment by convection. The heatsink can transfer heat to ambient air flowing along the heatsink.

Conventional heatsinks can include a plurality of fins that extend away from a base. The fins can be rectangular in shape and spaced away from each other so that the ambient air can flow along and between the fins. The fins and the base can be molded as a single, homogenous unit.

### SUMMARY

Some embodiments are directed to a heatsink for cooling an electric component of a power equipment. The heatsink can include a plurality of convective surfaces spaced away from and overlapping each other, and a first rivet connecting the convective surfaces to each other.

Some embodiments are directed to a heatsink that can include a mounting body, a plurality of fins spaced apart from each other and mounted onto the mounting body and a plurality of rivets connecting the fins to each other.

Some embodiments are directed to heatsink that can include a mounting, block, a plurality of fins and a plurality of rivets. The mounting block can have a rectangular parallelepiped shape having a first side with a first surface area and a second side with a second surface area that is greater than the first surface area. The plurality of fins can be spaced apart from each other and mounted onto the mounting body, and can include a first fin having a third surface area that is greater than the first surface area. The plurality of rivets connecting the fins to each other.

### BRIEF DESCRIPTION OF THE DRAWINGS

The disclosed subject matter of the present application will now be described in more detail with reference to exemplary embodiments of the apparatus and method, given by way of example, and with reference to the accompanying drawings, in which:

FIG. 1 is a perspective view of a power equipment made in accordance with principles of the disclosed subject matter.

FIG. 2 is an exploded perspective view of a power source assembly of the power equipment of FIG. 1.

FIG. 3 is perspective view of the power source assembly of FIG. 2 in an assembled state without the covers and showing convective heat transfer features of a heat sink.

FIG. 4 is a perspective view of the heat sink and electric components of the power equipment of FIG. 1.

FIG. 5 is a top view of the heatsink of FIG. 4.

FIG. 6 is a side view of the heatsink of FIG. 4.

FIG. 7 is an end view of the heatsink of FIG. 4.

FIG. 8 is a perspective view of the heatsink of FIG. 4.

FIG. 9 is a top view of a second embodiment of a heatsink for the power equipment of FIG. 1.

FIG. 10 is a side view of the heatsink of FIG. 9.

FIG. 11 is an end view of the heatsink of FIG. 9.

FIG. 12 is a perspective view of the heatsink of FIG. 9.

FIG. 13 is an end view of the heatsink of a third embodiment of a heatsink for the power equipment of FIG. 1.

FIG. 14 is a perspective view of the heatsink of FIG. 13.

FIG. 15 is an end view of the heatsink of a fourth embodiment of a heatsink for the power equipment of FIG. 1.

FIG. 16 is a perspective view of the heatsink of FIG. 15.

FIG. 17 is an end view of the heatsink of FIG. 15 mounted on the mounting body and printed circuit board shown in FIG. 4.

FIG. 18 is an end view of the heatsink of FIG. 15 mounted on a metal mounting plate.

FIG. 19 is a perspective view of the heatsink and metal mounting plate of FIG. 18.

### DETAILED DESCRIPTION OF EXEMPLARY EMBODIMENTS

A few inventive aspects of the disclosed embodiments are explained in detail below with reference to the various figures. Exemplary embodiments are described to illustrate the disclosed subject matter, not to limit its scope, which is defined by the claims. Those of ordinary skill in the art will recognize a number of equivalent variations of the various features provided in the description that follows.

Electric power tools, portable coolers, E-Bikes and scooters and other devices can be collectively referred to as power equipment. Electric power tools can include, but are not limited to, a lawnmower, a snow blower, a pressure washer, a tiller, a hedge trimmer, a string trimmer, a power saw and a fluid pump. The power equipment can include one or more electric components that generate heat during operation of the power equipment. The electric component can be, but is not limited to, a motor, a battery, a printed circuit board, a resistor, a capacitor, a transistor, or any combination of these devices and/or any number of each of these devices. The power equipment can include a heatsink that absorbs heat generated by the electric component(s) and transfers the absorbed heat to the ambient air.

The convective heat transfer rate is dictated by the surface area of the heatsink and the flow rate/volume of the ambient air flowing along the heatsink. The direction(s) along which the ambient air flows can limit the convective heat transfer rate. For example, the natural flow of the ambient air can be limited to one direction along the heatsink. As a result, the heat transfer rate at the downstream end of the heatsink can be less than the heat transfer rate at the upstream end of the heatsink due to the varying temperature of the air from the upstream location (lower temp) to downstream location (relatively higher temp). However, the flow direction(s) of the ambient air can be constrained by the size and shape of the power equipment and the packaging of the heatsink in or on the power equipment.

Other factors can constrain the thermal efficiency of the heatsink. For example, the space and/or weight desired for the power equipment can limit the surface area available for the heatsink. In another example, the desired weight balance of the power equipment when being held by the user can limit the surface area of the heatsink.

Thus, the efficiency of the heatsink and the maximum heat transfer rate can be limited by the desired parameters of the power equipment. In order to counter some of these drawbacks, the heatsink can be used in combination with a fan that forces ambient air to flow across the heatsink at an air flow rate/volume that dissipates the desired amount of heat in a desired time. The fan can be positioned relative to the heatsink so that the ambient air flows along the heatsink in two different directions. The increase in air flow rate/volume and the increase in flow directions can improve the heat transfer rate of the heatsink as compared to the same heatsink without a fan. However, the fan consumes electric power during operation of a battery powered power equipment. Thus, the battery power can be consumed faster as compared to the same power equipment that does not use a fan in combination with the heatsink. Further, the fan can direct dust, debris and/or fluids onto (or into) the electric component(s). The dust, debris and/or fluids can adversely affect the performance of the electric component(s). Further still, the fan can add weight and cost to the power equipment.

Thus, there is a need for a heatsink that can efficiently cool the electric component(s) of the power equipment using natural convection (i.e., no fan) that flows in a plurality of different directions. Further, there is a need for a heatsink that is smaller in weight and volume, costs less, and has an increased efficiency as compared to a conventional heatsink.

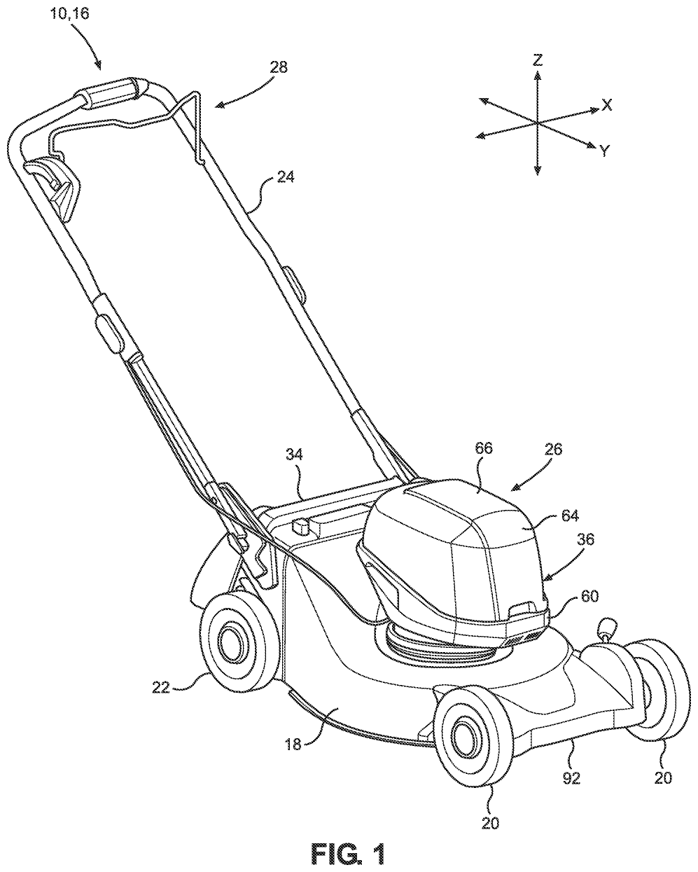

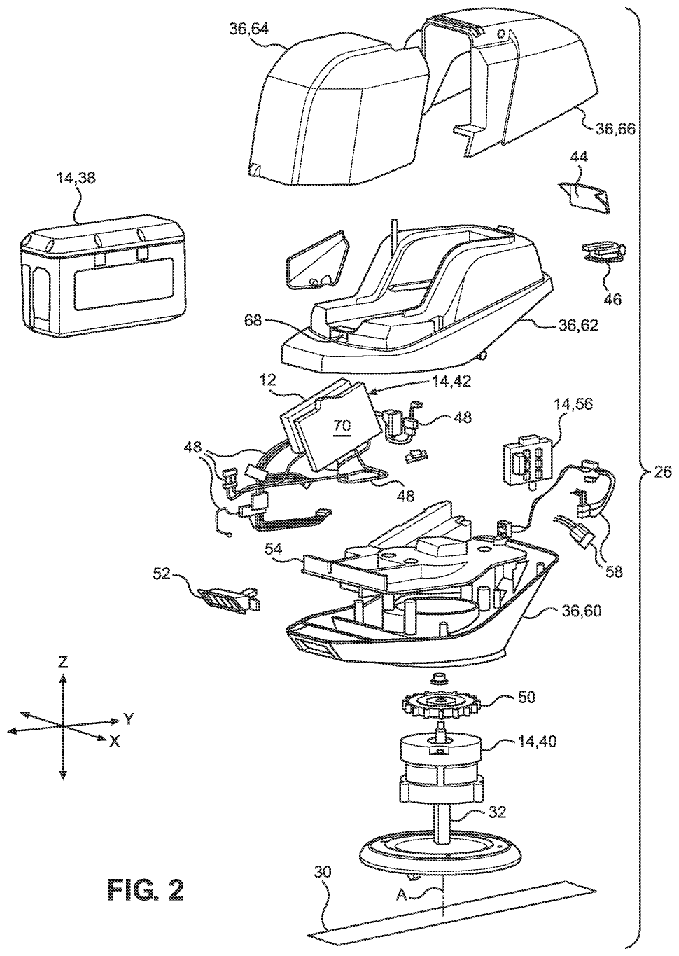

FIG. 1 illustrates an embodiment of a power equipment 10 made in accordance with principles of the disclosed subject matter. Referring to FIGS. 2-8, the power equipment 10 can include a heatsink 12 that uses natural convection with the ambient air to cool an electric component 14 of the power equipment 10. The heatsink 12 can have a higher efficiency, a lower surface temperature, a reduced weight, and a lower cost/performance ratio as compared to a conventional heatsink of the same surface area, which conventional heatsink includes fins and a base that are integrally molded as a homogenous unit.

FIG. 1 illustrates an embodiment of a power equipment 10 that is configured as a walk-behind self-propelled lawnmower 16. The lawnmower 16 can include a cutter housing 18, a pair of front wheels 20, a pair of rear wheels 22, a handle 24, a power source assembly 26, and a control system 28. The rear wheel 22 on the right side of the lawnmower 16 is obstructed from view in FIG. 1 by the cutter housing 18.

Referring to FIG. 2, the lawnmower 16 can include a blade 30 and a blade shaft 32 connected to each of the blade 30 and the power source assembly 26. The power source assembly 26 can be configured to selectively rotate the blade shaft 32 and the blade 30 in the cutter housing 18 about a blade axis A. The blade shaft 32 can be referred to as a component of the power source assembly 26. Alternatively, the blade shaft 32 can be referred to as a component that is connected to and driven by the power source assembly 26.

The lawnmower 16 can be described with respect to a coordinate system that includes an X-direction, a Y-direction and a Z-direction that are orthogonal to each other. The Z-direction can be parallel to the blade axis A.

The cutter housing 18 can be referred to as a mower deck or as a cutter deck or as a deck. Referring to FIG. 1, the cutter housing 18 can include an opening at a rear end 34 of the cutter housing 18. The lawnmower 16 can include a collection bag that can be selectively attached to and detached from the rear end 34. The opening and the collection bag are omitted for simplicity and clarity of the drawing figures. The collection bag can be in communication with the opening such that vegetation clippings produced by the blade 30 can be collected in the collection bag.

Returning to FIG. 2, the power source assembly 26 can include a housing 36 a battery pack 38, a blade motor 40, a blade motor driver 42, an LED display 44, a terminal block 46, a motor wire harness 48, a fan 50, a headlight assembly 52, a duct plate 54, a transmission controller 56, a transmission wire harness 58 and the control system 28 (FIG. 1). The housing 36 can contain the battery pack 38, the blade motor 40 the blade motor driver 42, the wire harnesses 48, 58, the fan 52 and the duct plate 54.

The housing 36 can include a lower housing 60, an upper housing 62, a front lid 64 and a rear lid 66.

The lower housing 60 can be mounted on the top of the cutter housing 18. The duct plate 54 can be mounted on the upper side of the lower housing 60 with respect to the Z-direction. The blade motor 40 and the fan 50 can be located inside the lower housing 60 and between the duct plate 54 and the top surface of the cutter deck 18 with respect to the Z-direction.

The upper housing 62 can be connected to the lower housing 60 and enclose the duct plate 54. The upper housing 62 can include a battery tray assembly 68 that receives the battery pack 38 and reliably secures the battery pack to the housing 36.

The rear lid 66 can be mounted onto the upper housing 62 so that the upper housing 62 and the rear lid enclose at least a portion of the battery pack 38 and the battery tray assembly 68. The front lid 64 can be connected to the rear lid 66 and the upper housing 62 so that the front lid 64 can be removed or moved between a closed position and an opened position. The front lid 66 and the upper housing 62 can enclose at least a portion of the battery pack 38 and the battery tray assembly 68 when the front lid 66 is mounted onto the upper housing 62 or placed into the closed position, as shown in FIG. 1.

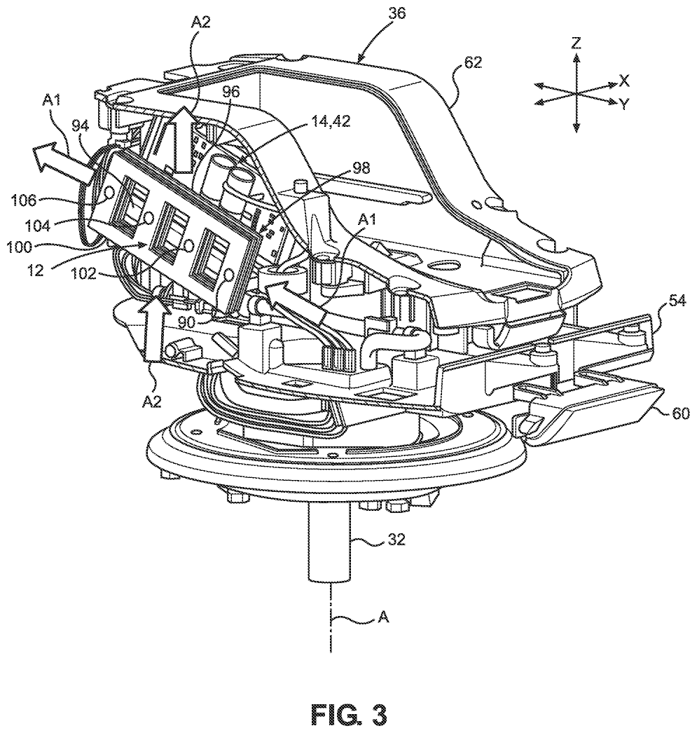

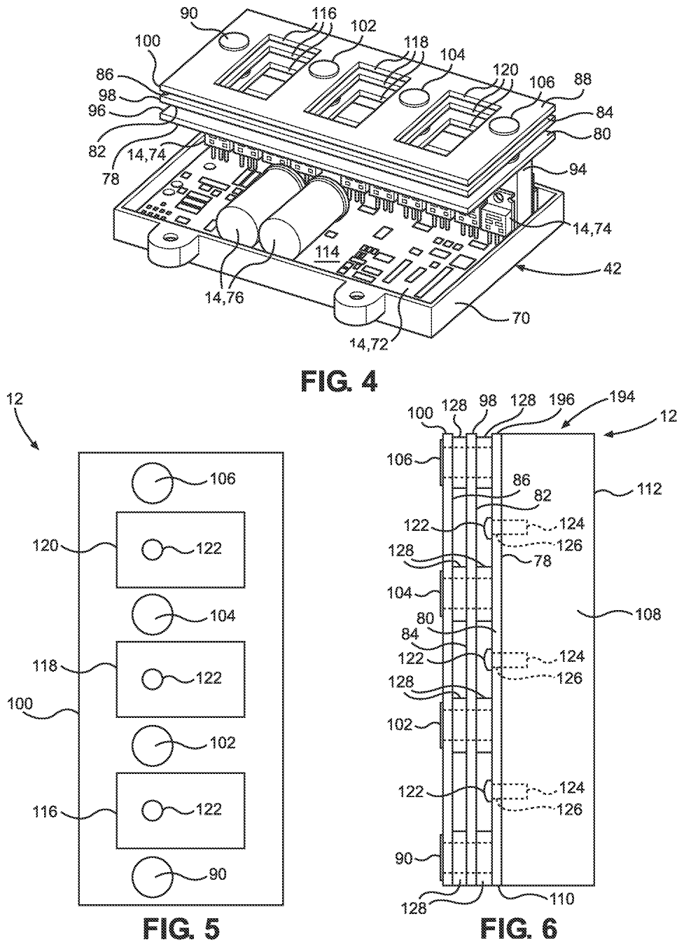

Referring to FIGS. 2-4, the heatsink 12 can be mounted onto the blade motor driver 42. Referring to FIG. 4, the blade motor driver 42 can include a mounting bracket 70, a printed circuit board 72, a plurality of power transistors 74 mounted onto the circuit board 72, a plurality of other electronic components 76 mounted onto the circuit board 72. Referring to FIG. 3, the mounting bracket 70 can be connected to the upper housing 62 inside a receptacle of the housing 36. A portion of each of the lower housing 60 and the upper housing 62 is cut away in FIG. 3 and the lids 64, 66 are omitted to reveal the receptacle of the housing 36 along with the heatsink 12 and the blade motor driver 42.

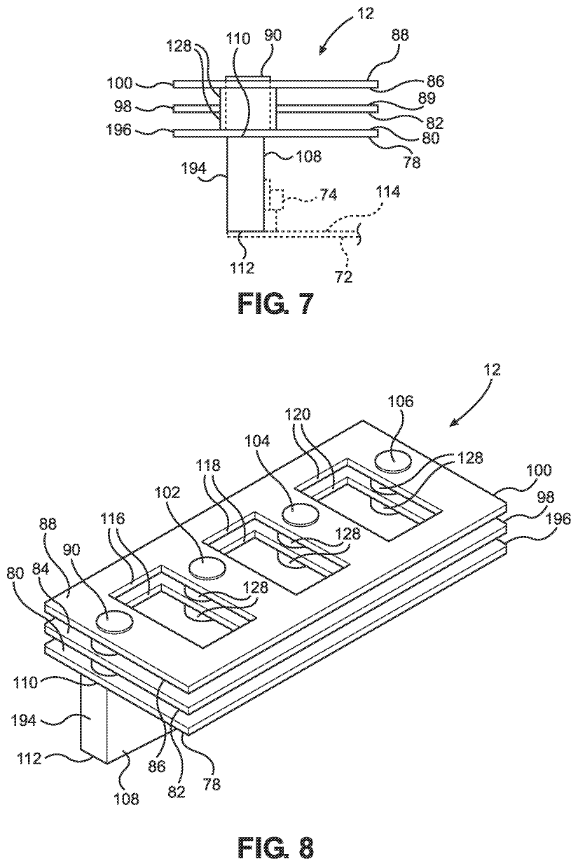

The printed circuit board 72 and one of the transistors 74 is shown in phantom in FIG. 7.

Referring to FIGS. 3-8, the heatsink 12 can include a plurality of convective surfaces 78, 80, 82, 84, 86, 88 and at least one rivet 90 that connects the convective surfaces 78, 80, 82, 84, 86, 88 to each other. The convective surfaces 78, 80, 82, 84, 86, 88 can be spaced away from and overlap each other in a direction that is orthogonal to the convective surfaces 78, 80, 82, 84, 86, 88. The combined surface area of the convective surfaces 78, 80, 82, 84, 86, 88 can be greater than the surface area of a conventional heat sink that occupies the same or substantially the same volume as the heatsink 12. Thus, the heatsink 12 can have a greater thermal efficiency as compared to a conventional heatsink such as a casting in which the fins are integrally formed with a base to make a homogenous unit.

Even though the convective surfaces 78, 80, 82, 84, 86, 88 are spaced away from each other, the first rivet 90 can connect the convective surfaces 78, 80, 82, 84, 86, 88 to each other in a single manufacturing step. Thus, the manufacture of the heatsink 12 can be comparable to a single step of casting a conventional heatsink from a molten metal material.

Referring to FIG. 3, ambient air can flow along each of the convective surfaces 78, 80, 82, 84, 86, 88 in a first direction, as indicated by first arrows A1 and in a second direction, as indicated by the second arrows A2. The first arrows A1 can point in a direction that is generally parallel to the Y-direction and in a direction from a front end 92 (FIG. 1) of the cutter housing 18 toward the rear end 34 (FIG. 1) of the cutter housing 18. The first direction can be slightly inclined with respect to the Y-direction such that the ambient air exits the heatsinks 12 at an elevation in the Z-direction that is higher than the elevation at which the ambient airs enters the heatsink 12. The second arrows A2 can point in a direction that is generally parallel to the Z-direction and in a direction from a bottom of the cutter housing 18 toward a top of the housing 36. Since the ambient air can flow through the heatsink 12 in two different directions, it is possible to rely on natural convection to transfer heat from the heatsink to the ambient air. Thus, a cooling fan can be omitted from the lawnmower 16.

Referring to FIGS. 3 and 4, the heatsink 12 can include a mounting body 94 and a first fin 96 as shown in FIGS. 3 and 4 or the heatsink 12 can include a mounting body 194 and a first fin 196 as shown in FIGS. 6-8. Referring to FIGS. 3-8, the heatsink 12 can include a second fin 98, a third fin 100 and a plurality of rivets 90, 102, 104, 106 that connects the fins 96, 98, 100 to each other or the fins 196, 98, 100 to each other. Each of the rivets 90, 102, 104, 106 can extend through each of the fins 96, 98, 100, 196. The first fins 96, 196 can include the first convective surface 78 and the second convective surface 80. The second fin 98 can include the first convective surface 82 and the second convective surface 84. The third fin 100 can include the first convective surface 86 and the second convective surface 88.

Either of the mounting bodies 94, 194 can be connected to the printed circuit board 72 in any appropriate manner such as, but not limited to mechanical fasteners, adhesive, weld, or solder. Each of the mounting bodies 94, 194 can space the respective fins 96, 98, 100, 196 away from the printed circuit board 72 and all of the electric components mounted on the printed circuit board 72. Referring to FIGS. 4 and 7, each of the convective surfaces 78, 80, 82, 84, 86, 88 can be parallel or substantially parallel to a main surface 114 of the printed circuit board 72 such that one of ordinary skill in the art would consider the surfaces 78, 80, 82, 84, 86, 88, 114 to be parallel to each other. The circuit board 72 and the transistor 74 are shown in phantom in FIG. 7.

Referring to FIGS. 4 and 6-8 collectively, the mounting bodies 94, 194 can be a rectangular block that includes a rectangular first surface 108, a rectangular second surface 110 and a rectangular third surface 112. The first surface 108 can have a first surface area and each of the second surface 110 and the third surface 112 can have a second surface area that is smaller than the first surface area.

The first surface 108 can be thermally coupled to each of the transistors 74, as shown in FIGS. 4 and 7. The second surface 110 can be connected to and extend away from the first surface 108 at a right angle. The first fin 96 can be mounted on the second surface 110. The third surface 112 can be connected to and extend away from the first surface 108 at a right angle. The third surface 112 can be spaced away from and parallel to the second surface 110. The third surface 112 can abut and be thermally coupled to the printed circuit board 72.

Either of the mounting blocks 94, 194 can extend away from either of the first fins 96, 196 in a direction that is orthogonal to the convective surfaces 78, 80, 82, 84, 86, 88. The first surface 108 of the mounting blocks 94, 194 can be orthogonal to the convective surfaces 78, 80, 82, 84, 86, 88 and the second and third surfaces 110, 112 can be parallel to the convective surfaces 78, 80, 82, 84, 86, 88.

The fins 96, 98, 100 196 can be stamped from a sheet of metal such as, but not limited to, aluminum or steel. Referring to FIGS. 3 and 4, the fins 96, 98, 100 can be identical to each other. The fins 96, 98, 100 can have a rectangular shape and be referred to as rectangular plates. Each of the fins 96, 98, 100 can include a plurality of openings 116, 118, 120. The first openings 116 can be aligned with each other, the second openings 118 can be aligned with each other, and the third openings 120 can be aligned with each other. The first openings 116 can be located between the first rivet 90 and the second rivet 102, the second openings 118 can be located between the second rivet 102 and the third rivet 104, and the third openings 120 can be located between the third rivet 104 and the fourth rivet 106.

The openings 116, 118, 120 can have a rectangular shape. Each of the fins 96, 98, 100 can be elongated in a first direction and each of the openings 116, 118, 120 can be elongated in a second direction that is perpendicular to the first direction.

Referring to FIGS. 5 and 8, the openings 116, 118, 120 can be omitted from the first fin 196. That is, the first fin 196 can be a solid rectangular plate.

The first fins 96, 196 can be mounted onto the respective mounting body 94, 194 in any appropriate manner such as, but not limited, mechanical fasteners, welding, or adhesive. For example, referring to FIGS. 5 and 6, a plurality of screw stoppers 122 can connect the mounting block 194 to the first fin 196. The mounting block 194 can include a plurality of bores 124 and the first fin 196 can include a plurality of bores 126 shown in phantom in FIG. 6. A respective one of the screw stoppers 122 can pass through a respective pair of the bores 124, 126.

The heatsink 12 can include a plurality of spacers 128 located between each pair of the fins 96 (or 196), 98, 100. The spacers 128 can separate the fins 96 (or 196), 98, 100 from each other. The spacers 128 can be rings that are separate from the fins 96 (or 196), 98, 100. A respective one of the rivets 90, 102, 104, 106 extends through a respective pair of the spacers 128. Respective spacers 128 can protrude from the second convective surface 80 of the first fin 96 (or 196), the first convective surface 82 and the second convective surface 84 of the second fin 98, and the first convective surface 86 of the third fin 100.

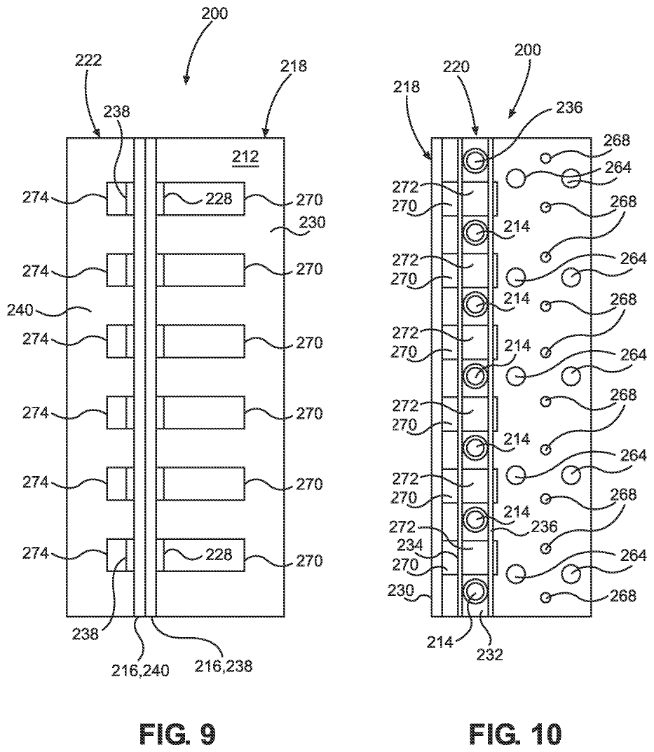

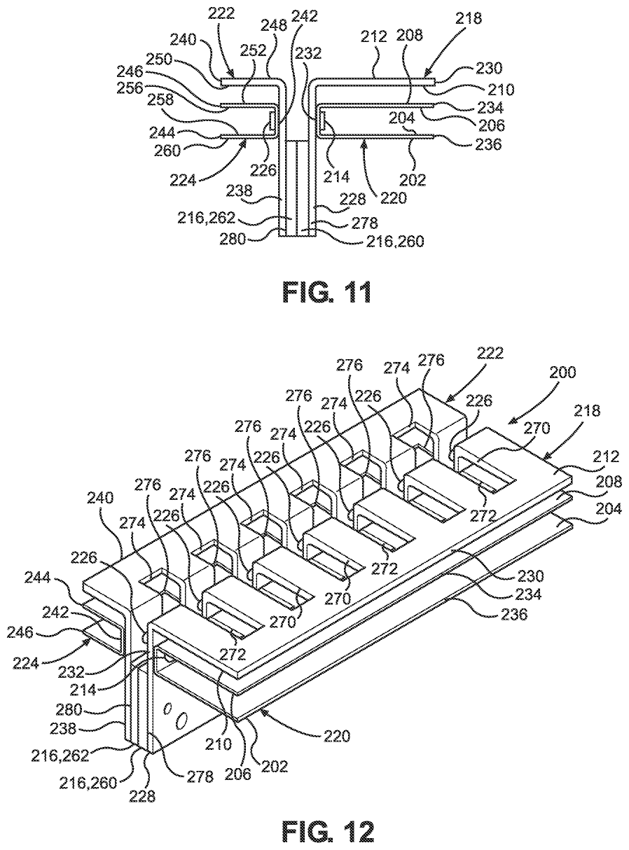

FIGS. 9-12 show a heatsink 200 according to a second embodiment of the disclosed subject matter. Referring to FIGS. 11 and 12, the heatsink 200 can include a plurality of convective surfaces 202, 204, 206, 208, 210, 212 and at least one rivet 214 that connects the convective surfaces 202, 204, 206, 208, 210, 212 to each other. The convective surfaces 202, 204, 206, 208, 210, 212 can be spaced away from and overlap each other in a direction that is orthogonal to the convective surfaces 202, 204, 206, 208, 210, 212. The combined surface area of the convective surfaces 202, 204, 206, 208, 210, 212 can be greater than the surface area of a conventional heat sink that occupies the same or substantially the same volume as the heatsink 200. Thus, the heatsink 200 can have a greater thermal efficiency as compared to a conventional heatsink such as a casting in which fins are integrally formed with a base to make a homogenous unit.

Even though the convective surfaces 202, 204, 206, 208, 210, 212 are spaced away from each other, the first rivet 214 can connect the convective surfaces 202, 204, 206, 208, 210, 212 to each other in a single manufacturing step. Thus, the manufacture of the heatsink 200 can be comparable to a single step of casting a conventional heatsink from a molten metal material.

As with the heatsink 12 shown in FIG. 3, ambient air can flow along each of the convective surfaces 202, 204, 206, 208, 210, 212 in a first direction, as indicated by first arrows A1 (FIG. 3) and in a second direction, as indicated by the second arrows A2 (FIG. 3). Since the ambient air can flow through the heatsink 200 in two different directions, it is possible to rely on natural convection to transfer heat from the heatsink to the ambient air. Thus, a cooling fan can be omitted from a lawnmower 16 that includes heatsink 200.

The heatsink 200 can include a mounting body 216, a plurality of fins 218, 220, 222, 224 and a plurality of first rivets 214 that connect the fins 218, 220 to each other and a plurality of second rivets 226 (FIGS. 11 and 12) that connect the fins 222, 224 to each other. Each of the first rivets 214 can extend through each of the first and second fins 218, 220 and each of the second rivets 226 can extend through the third and fourth fins 222, 224. The first fin 218 can include the first convective surface 210 and the second convective surface 212. The second fin 220 can include the first convective surface 202, the second convective surface 204, the third convective surface 206 and the fourth convective surface 208.

The mounting body 216 can be a rectangular parallelepiped or block that includes a first surface 278 and a second surface 280 that is on a side of the mounting body 216 that is opposite to the first surface 278. The first fin 218 can abut the first surface 278 and the third fin 222, can abut the second surface 280.

The first fin 218 can include a first mounting plate 228 and a fin plate 230 and the second fin 220 can include a second mounting plate 232 and a pair of fin plates 234, 236. The second mounting plate 232 can abut the first mounting plate 228 and the first rivets 214 can extend through the mounting plates 228, 232. The fin plates 230, 234, 236 can be spaced apart from each other in a direction that is orthogonal to the convective surfaces 202, 204, 206, 208, 210, 212. The first fin plate 230 can extend from the first mounting plate 228 in a direction that is orthogonal to the first mounting plate 228. The second and third fin plates 234, 236 can extend from the second mounting plate 232 in direction that is orthogonal to the second mounting plate 232 and parallel to the first fin plate 230.

The third fin 222 can include a third mounting plate 238 and a fourth fin plate 240 and the fourth fin 224 can include a fourth mounting plate 242 and a pair of fin plates 244, 246. The fourth mounting plate 242 can abut the third mounting plate 238 and the second rivets 226 can extend through the mounting plates 238, 242. The fourth fin plate 240 can extend from the third mounting plate 238 in a direction that is orthogonal to the third mounting plate 238. The fifth and sixth fin plates 244, 246 can extend from the fourth mounting plate 242 in a direction that is orthogonal to the fourth mounting plate 242 and parallel to the fourth fin plate 240.

Referring to FIG. 11, the third fin 222 can include a pair of convective surfaces 248, 250 and the fourth fin 224 can include a plurality of convective surfaces 252, 254, 256, 258. The fin plates 240, 244, 246 can be spaced apart from each other in a direction that is orthogonal to the convective surfaces 248, 250, 252, 254, 256, 258.

The mounting body 216 can include a fifth mounting plate 260 and a sixth mounting plate 262 that abuts and overlaps the fifth mounting plate 260 to form a rectangular parallelepipedor block. The fifth mounting plate 260 can include the first surface 278 and the sixth mounting plate 262 can include the second surface 280. The first mounting plate 228 can abut and overlap the fifth mounting plate 260 and the third mounting plate 238 can abut and overlap the sixth mounting plate 262. A plurality of third rivets 264 can connect the mounting plates 228, 238, 260, 262.

The mounting body 216 can be connected to the printed circuit board 72 in any appropriate manner such as, but not limited to mechanical fasteners, adhesive, weld, or solder. The mounting body 216 and the mounting plates 228, 232 can space the fins plates 230, 234, 236 away from the printed circuit board 72 and all of the electric components mounted on the printed circuit board 72. Each of the convective surfaces 202, 204, 206, 208, 210, 212 can be parallel or substantially parallel to a main surface 114 (FIG. 4) of the printed circuit board 72 such that one of ordinary skill in the art would consider the convective surfaces 202, 204, 206, 208, 210, 212 to be parallel to each other.

Referring to FIG. 10, the first mounting plate 228 can include a rectangular mounting surface 266. The mounting surface 266 can be thermally coupled to each of the transistors 74. The mounting surface 266 can be orthogonal to the convective surfaces 202, 204, 206, 208, 210, 212. The first mounting plate 228 can include a plurality of holes 268 for connecting the transistors 74 to the first mounting plate 228. A pair of threaded fasteners (not shown) can pass through a respective one of the transistors 74 and a respective pair of the holes 268.

Referring to FIGS. 9-12, the fins 218, 220, 222, 224 can be stamped from a sheet of metal such as, but not limited to, aluminum or steel. The fins 218, 220, 222, 224 can be bent to form the respective mounting plate 228, 232, 238, 242 and the respective fin plate(s) 230, 234, 236, 240, 244, 246. That is, the first fin plate 230 can extend away from the first mounting plate 228 at an angle and be continuous with the first mounting plate 228, the second and third fin plates 234, 236 can extend away from the second mounting plate 232 at an angle and be continuous with the second mounting plate 232, the fourth fin plate 240 can extend away from the third mounting plate 238 at an angle and be continuous with the third mounting plate 238, the fifth and sixth fin plates 244, 246 can extend away from the fourth mounting plate 242 at an angle and be continuous with the fourth mounting plate 242.

Referring to FIGS. 9, 10 and 12 collectively, the first fin 218 can include a plurality of first openings 270, the second fin 220 can include a plurality of second openings 272, the third fin 222 can include a third plurality of openings 274, and the fourth fin 224 can include a plurality of fourth openings 276. The first openings 270 can extend along the first mounting plate 228 and the first fin plate 230, the second openings 272 can extend along the second mounting plate 232 and each of the second fin plate 234 and the third fin plate 236, the third openings 274 can extend along the third mounting plate 238 and the fourth fin plate 240, and the fourth openings 276 can extend along the fourth mounting plate 242 and each of the fifth fin plate 244 and the sixth fin plate 246. The first openings 270 can be aligned with and overlap the second openings 272, and the third openings 274 can be aligned with and overlap the fourth openings 276. The first and second openings 270, 272 can be located between a respective pair of the first rivets 214, and third and fourth openings 274, 276 can be located between a respective pair of the second rivets 226.

The plates 228, 230, 232, 234, 236, 238, 240, 242, 244, 246 can have a flat rectangular shape and be referred to as flat rectangular plates. The plates 228, 230, 232, 234, 236, 238, 240, 242, 244, 246 can be elongated in a first direction. The openings 270, 272, 274, 276 can have a rectangular shape that is elongated in a second direction that is perpendicular to the first direction.

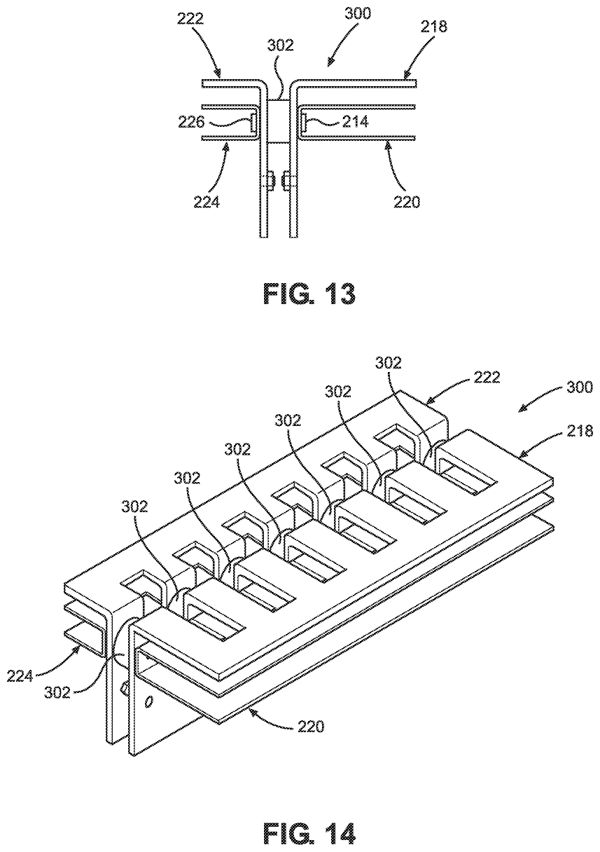

FIGS. 13 and 14 illustrate a third embodiment of a heatsink 300 that can have the same structure as the heatsink 200 shown in FIGS. 9-12, except that a plurality of rods 302 replace the mounting body 216. The remaining structure shown in FIGS. 13 and 14, including the rivets 214, 226 and the fins 218, 220, 222, 224, can be the same as or similar to described above with respect to FIGS. 9-12.

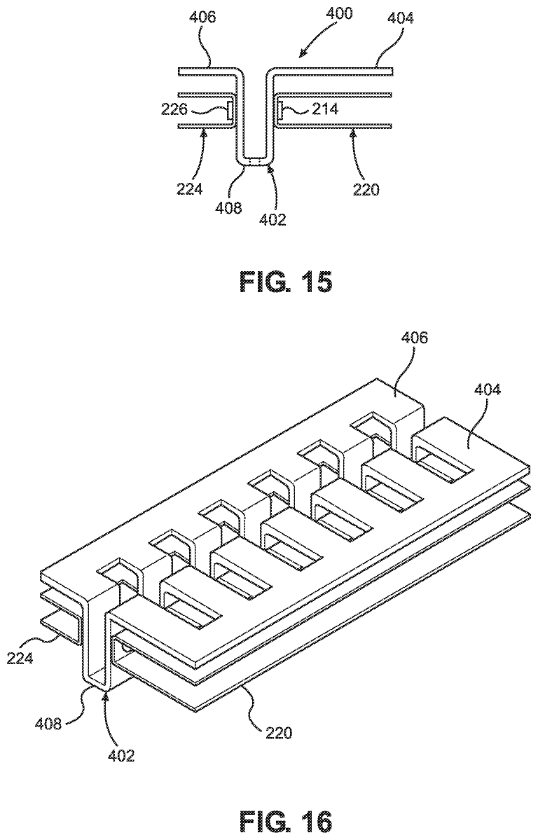

FIGS. 15-19 illustrate a fourth embodiment of a heatsink 400 that can be similar to heatsink 200 of FIGS. 9-12. Instead of the two separate fins 218, 220 of the heatsink 200, the heatsink 400 can include a fin body 402 that includes a first fin 404, a second fin 406 and a connector body 408 that can be formed by bending and/or stamping a flat plate into the shape shown in FIGS. 15-19. Each of the fins 404, 406 can have a L-shape as viewed in FIG. 15 and the connector body 408 can be a straight flat portion of the fin body 402 that is connected to and extends from the bottom ends of the fins 404, 406.

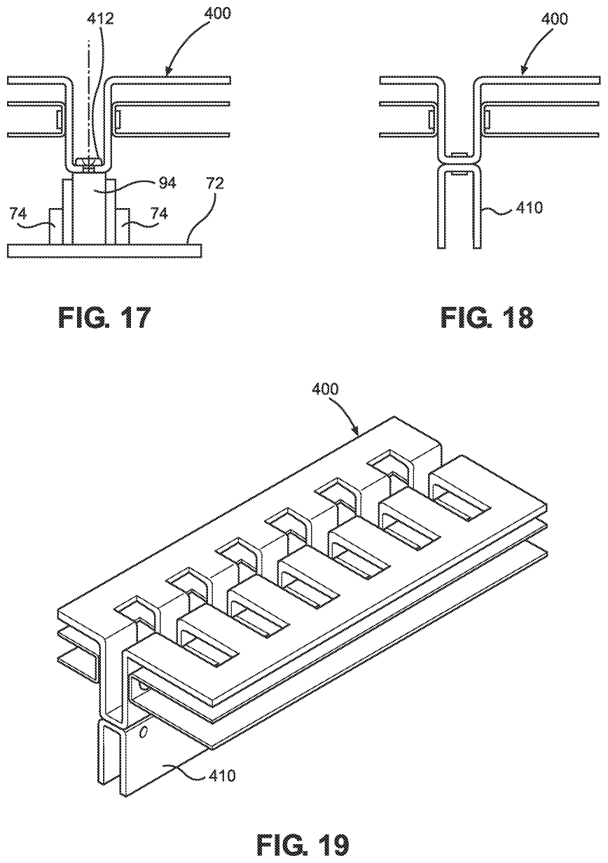

The heatsink 400 can be mounted on a mounting structure such as the mounting body 94 described above with respect to FIG. 4. Referring to FIG. 17, a plurality of fasteners 412 can connect the connector body 408 to the mounting body 94.

Referring to FIGS. 18 and 19, instead of mounting the heatsink 400 onto the mounting body 94, the heatsink 400 can be mounted on a mounting body 410 that has a U-shape as viewed in FIG. 18. The mounting body 410 can be formed by bending and/or stamping a flat metal plate into the shape shown in FIGS. 18 and 19. The shape of the mounting body 410 as shown in FIGS. 18 and 19 is an inverted U-shape. However, many other shapes are possible including cylindrical, asymmetrical, or parallelepiped, for the mounting body 410. Other elements of the heat sink 400 can also be variously shaped depending on space requirements and particular application requirements.

Each of the battery 38, the motor 40, the blade motor driver 42, the transmission controller 44, the printed circuit board 70, the transistor 74, the electronic component 76 can be referred to as an electric component 14. In addition to the heat sink 12 or heatsink 200 on the blade motor driver 42, a respective heatsink 12 or the heatsink 200 can be mounted onto or otherwise thermally coupled with any of the other electric components 14.

Each of the heatsinks 12, 200 can permit ambient air to flow in at least two different directions across/through the heatsinks 12, 200 and can have a large surface area relative to the volume occupied by the heatsinks 12, 200. Thus, the heatsinks 12, 200 can efficiently cool the electric component(s) 14 of the power equipment 10 using natural convection (i.e., no fan). Further, the heatsinks 12, 200 can be smaller in weight and volume, costs less, and have an increased efficiency as compared to a conventional heatsink.

The control system 28 can include input(s) such as, but not limited to, a lever, a button, a dial, or a touch screen that permits the operator of the lawnmower 16 to control the operation of the blade 30 and the travel speed of the lawnmower 16. The control system 28 can be in electrical communication with the blade motor driver 42 and the transmission controller 56.

The lawnmower 16 can be self-propelled by a transmission motor that is not shown. The transmission wire harness 58 can electrically connect the transmission controller 56 to the battery pack 38 and the transmission motor. The transmission controller 56 can be configured to operate the transmission motor based on an input signal received from the control system 28.

Returning to FIG. 2, the housing 36 can include an access panel 282 that is removably connected to a side of the upper housing 62. The access panel 282 can be removed from the upper housing 62 to permit access to the blade motor driver 42.

While certain embodiments of the invention are described above, it should be understood that the invention can be embodied and configured in many different ways without departing from the spirit and scope of the invention.

F For example, embodiments are disclosed above in the context of the walk-behind lawnmower 16 shown in FIG. 1. However, the heatsink can be used for any power equipment described above. Further, embodiments can include any type of lawnmower. For example, alternate embodiments can include a ride-on lawnmower, a zero-turn-radius walk-behind lawnmower or a zero-turn-radius ride-on lawnmower.

Alternate embodiments of the heatsink can include any number of fins in order to achieve the desired convective heat transfer rate.

The heatsink 12 described above can include openings in each of the fins 96, 98, 100 or the solid fin 196 in place of the fin 96 with the openings 116, 118, 120. However, exemplary embodiments can include a plurality of solid fins 196 and omit the fins 98, 100.

The heatsinks 12, 200 described above can have fins or fin plates that extend orthogonal to the respective mounting body 94, 216. However, exemplary embodiments can include fins or fin plates that extend away from the mounting body at an oblique angle.

The heatsinks 12, 200 described above can have fins or fin plates that are rectangular in shape. However, exemplary embodiments can include fins that have any desired shape, including asymmetrical shapes, polygonal shapes, round or oval shapes, etc. Similarly, the opening are depicted as rectangular in shape. However, it is contemplated that the opening in the plates can be various shapes and sizes, including circular, oval, asymmetrical, square, or other shape that allows for ventilation to occur between plates. In addition, the alignment of the openings can be varied and still fall within the scope of the disclosed subject matter. For example, the openings can be slightly offset between plates, or can be completely offset and non-overlapping.

Depending on the application, certain of the plates may have no openings, while others include openings.

The heatsink 12, 200 described above can be mounted inside of and enclosed by the housing 36. However, exemplary embodiments of the power equipment 12 can include the heatsink 12 or the heatsink 200 that is exposed outside of the power equipment 10.

In an alternate embodiment, the spacers 128 can be integrated with the third fin 100 and the second fin 98 by welding or bonding the spacers 128 onto the fins 98, 100.

What is claimed is:

1. A heatsink for cooling an electric component of a power equipment, the heatsink comprising:
a plurality of convective surfaces spaced away from and overlapping each other; and
a first rivet connecting the convective surfaces to each other.

2. The heatsink according to claim 1, further comprising:
a mounting body including,
a first surface that is configured to be thermally coupled to the electric component, and
a second surface that is connected to the first surface and extends away from the first surface at an angle; and
a plurality of fins mounted onto one of the first surface and the second surface, each of the fins includes a respective one of the convective surfaces.

3. The heatsink according to claim 2, wherein
the plurality of fins includes,
a first fin mounted onto the one of the first surface and the second surface, the first fin includes a first hole extending through the first fin, and
a second fin mounted onto and overlapping the first fin, the second fin includes a second hole extending through the second fin, and the second hole is aligned with the first hole, and
the first rivet extends through the first fin and the second fin and is spaced away from the first hole and the second hole.

4. The heatsink according to claim 3, wherein
the first fin is mounted onto the second surface and spaced away from the first surface, and
each of the first fin and the second fin is a rectangular plate.

5. The heatsink according to claim 3, wherein
the first fin is mounted onto the first surface,
each of the first fin and the second fin includes a mounting plate and a fin plate continuous with and extending away from the mounting plate at an angle, and each of the fin plates is spaced away from the first surface and the second surface.

6. The heatsink according to claim 3, further comprising:
a second rivet connecting the first fin to the second fin, wherein
the first hole and the second hole are located between the first rivet and the second rivet,
the first fin includes a third hole and the second fin includes a fourth hole,
the second rivet is located between the first hole and the third hole and between the second hole and the fourth hole.

7. The heatsink according to claim 6, wherein
the mounting body is a rectangular block,
the first surface has a first area and the second surface has a second area that is larger than the first area, and
the second surface is configured to abut the electric component when the heatsink and the electric component are installed on the power equipment.

8. An electric power equipment, comprising:
the heatsink according to claim 7;
a housing; and
a battery connected to the housing, wherein
the electric component is contained in the housing and electrically connected to the battery,
the heatsink abuts one of the battery and the electric component, and
the housing is devoid of a fan in fluid communication with the heatsink.

9. The heatsink according to claim 2, wherein at least one of the fins includes a plurality of rectangular openings.

10. The heatsink according to claim 9, further comprising:
a mounting block abutting the first fin, wherein
the mounting block extends away from the convective surfaces in a direction that is orthogonal to the convective surfaces.

11. A heatsink for cooling an electric component of a power equipment, the heatsink comprising:
a mounting body;
a plurality of fins spaced apart from each other and mounted onto the mounting body; and
a plurality of rivets connecting the fins to each other.

12. The heatsink according to claim 11, wherein
the plurality of fins includes a first fin and a second fin, each of the first fin and the second fin is a rectangular plate that includes a flat convective surface,
the first fin abuts the mounting body and includes a plurality of spacers protruding from the convective surface,
the second fin abuts each of the spacers and is spaced away from the convective surface of the first fin by each of the spacers, and
each of the rivets extends through a respective one of the spacers.

13. The heatsink according to claim 11, wherein
the plurality of fins includes,
a first fin including a first mounting plate and first fin plate continuous with and extending away from the first mounting plate at an angle, and
a second fin including a second mounting plate, a second fin plate continuous with and extending away from the second mounting plate at an angle,
the first mounting plate abuts the mounting block,
the second mounting plate abuts the first mounting plate, and
the rivets extend through the first mounting plate and the second mounting plate.

14. The heatsink according to claim 13, wherein
the second fin includes a third fin plate continuous with and extending away from the second mounting plate at an angle,
the first fin includes a plurality of first openings that extend along each of the first mounting plate and the first fin plate,
the second fin includes a plurality of second openings that extend along each of the second mounting plate, the second fin plate, and the third fin plate,
each of the first openings is located between a respective pair of the rivets, and
each of the second openings is located between a respective pair of the rivets.

15. The heatsink according to claim 13, further comprising:
a plurality of second rivets, wherein
the plurality of fins includes
a third fin including a third mounting plate and third fin plate continuous with and extending away from the third mounting plate at an angle, and
a fourth fin including a fourth mounting plate, a fourth fin plate continuous with and extending away from the fourth mounting plate at an angle,
the fourth mounting plate abuts the third mounting plate,
the second rivets extend through the third mounting plate and the fourth mounting plate,
the mounting block includes a first side and a second side that is opposite to the first side,
the first mounting plate abuts the first side,
the third mounting plate abuts the second side,
the first fin plate and second fin plate extend away from the first side in a first direction, and
the third fin plate and the fourth fin plate extend away from the second side in a second direction that is opposite to the first direction.

16. A heatsink for cooling an electric component of a power equipment, the heatsink comprising:
a mounting block having a first side with a first surface area and a second side with a second surface area that is greater than the first surface area;
a plurality of fins spaced apart from each other and mounted onto the mounting block, the plurality of fins includes a first fin having a third surface area that is greater than the first surface area, the plurality of fins are stacked with respect to each other and at least some of the plurality of fins include an opening therein that aligns with an opening of a respective adjacent stacked fin.

17. The heatsink according to claim 16, wherein
the first fin includes a first mounting plate and a first fin plate that is continuous with and perpendicular to the mounting plate,
the plurality of fins includes a U-shaped fin including a second mounting plate, a second fin plate continuous with and perpendicular to the second mounting plate, and a third fin plate continuous with and perpendicular to the second mounting plate,
the first mounting plate abuts the mounting block,
the second mounting plate abuts the first mounting plate.

18. The heatsink according to claim 17, further comprising;
a plurality of rivets connecting the fins to each other, wherein the mounting block includes a first flat rectangular plate and a second flat rectangular plate abutting and connected to the first flat rectangular plate.

19. The heatsink according to claim 16, wherein
the first fin is a rectangular plate that abuts the first surface and extends parallel to the first surface and perpendicular to the second surface,
the first fin includes,
a convective surface that is parallel to the first surface, and
a plurality of spacers adjacent the convective surface,
the plurality of fins include a second fin that is a rectangular plate that is parallel to the first fin and spaced away from the first fin by the spacers, and
a plurality of rivets extends through the first fin, the second fin, and a respective one of the spacers.

20. The heatsink according to claim 19, wherein
the first fin includes a plurality of first openings,
the second fin includes a plurality of second openings, and
each of the openings is located between a respective pair of the rivets.
